(19) United States
(12) Patent Application Publication
(10) Pub. No.: US 2015/0137317 A1
(43) Pub. Date: May 21, 2015

(54) SEMICONDUCTOR WAFER, METHOD OF PRODUCING A SEMICONDUCTOR WAFER AND METHOD OF PRODUCING A COMPOSITE WAFER

(71) Applicants: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP)

(72) Inventors: Takenori OSADA, Tsukuba-shi (JP); Tomoyuki TAKADA, Tsukuba-shi (JP); Masahiko HATA, Phoenix, AZ (US); Tetsuji YASUDA, Tsukuba-shi (JP); Tatsuro MAEDA, Tsukuba-shi (JP); Taro ITATANI, Tsukuba-shi (JP)

(73) Assignees: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP)

(21) Appl. No.: 14/568,165

(22) Filed: Dec. 12, 2014

Related U.S. Application Data
(63) Continuation-in-part of application No. PCT/JP2013/003752, filed on Jun. 14, 2013.

(30) Foreign Application Priority Data
Jun. 15, 2012 (JP) 2012-136445

(51) Int. Cl. H01L 29/267; H01L 21/02

(52) U.S. Cl. CPC H01L 29/267; H01L 21/02538; H01L 21/02455
USPC 257/615; 438/458

(57) ABSTRACT

A semiconductor wafer is provided. The semiconductor wafer comprises a sacrificial layer and a semiconductor crystal layer above a semiconductor crystal layer forming wafer, the semiconductor crystal layer forming wafer, the sacrificial layer and the semiconductor crystal layer being arranged in the order of the semiconductor crystal layer forming wafer, the sacrificial layer and the semiconductor crystal layer, wherein the semiconductor wafer comprises a diffusion inhibiting layer that inhibits diffusion of a first atom of one type selected from a plurality of types of atoms constituting the semiconductor crystal layer forming wafer or the sacrificial layer, at any cross-sectional position between (a) the interface of the semiconductor crystal layer forming wafer that faces the sacrificial layer and (b) a middle of the semiconductor crystal layer.

The contents of the following patent applications are incorporated herein by reference:
NO. 2012-136445 filed in Japan on Jun. 15, 2012, and
NO. PCT/JP2013/003752 filed on Jun. 14, 2013.

### BACKGROUND

1. Technical Field

The present invention relates to a semiconductor wafer, a method of producing a semiconductor wafer, and a method of producing a composite wafer.

2. Related Art

Group III-V compound semiconductors such as GaAs and InGaAs have high electron mobility. On the other hand, Group IV semiconductors such as Ge and SiGe have high hole mobility. Therefore, a highly advanced complementary metal-oxide-semiconductor field effect transistor (CMOSFET) can be realized if the Group III-V compound semiconductors are used to form an N-channel metal-oxide-semiconductor field effect transistor (MOSFET) (hereinafter, may be simply referred to as nMOSFET) and the Group IV semiconductors are used to form a P-channel MOSFET (hereinafter, may be simply referred to as “pMOSFET”). Non-Patent Document 1 discloses a CMOSFET structure in which an N-channel MOSFET having a channel made of a Group III-V compound semiconductor and a P-channel MOSFET having a channel made of Ge are formed on a single wafer.

To form heterogeneous materials of a Group III-V compound semiconductor layer and a Group IV semiconductor crystal layer on a single wafer (for example, a silicon wafer), a technique is known to transfer onto the single wafer a semiconductor crystal layer that has been formed on a crystal growth wafer. For example, Non-Patent Document 2 discloses a technique according to which an AlAs layer is formed as a sacrificial layer on a GaAs wafer and a Ge layer is formed on the sacrificial layer (AlAs layer) and transferred onto a silicon wafer.

### PRIOR ART DOCUMENTS

### Non-Patent Documents

Non-Patent Document 1: S. Takagi, et al., SSE, vol. 51, pp. 526-536, 2007.

Non-Patent Document 2: Y. Bai and E. A. Fitzgerald, ECS Transactions, 33 (6) 927-932 (2010)

To form on a single wafer an N-channel metal-insulator-semiconductor field effect transistor (MISFET) (hereinafter, may be simply referred to as “nMISFET”) having a channel made of a Group III-V compound semiconductor and a P-channel MISFET (hereinafter, may be simply referred to as “pMISFET”) having a channel made of a Group IV semiconductor, it is necessary to develop a technique of forming the Group III-V compound semiconductor for the n-MISFET and the Group IV semiconductor for the p-MISFET on the single wafer. Furthermore, taking into consideration that the single wafer is produced as a large scale integration (LSI), it is preferable to form a Group III-V compound semiconductor crystal layer for the nMISFET and a Group IV semiconductor crystal layer for the pMISFET on a silicon wafer, which makes it possible to make use of existing production apparatuses and methods.

In some cases, a semiconductor crystal layer for transfer is formed by: using a Group III-V compound single crystal wafer such as GaAs as a semiconductor crystal layer forming wafer; using a Group III-V compound semiconductor crystal layer such as AlAs as a sacrificial layer for peeling off a semiconductor crystal layer from the semiconductor crystal layer forming wafer by etching; and performing epitaxial growth of a Group IV semiconductor such as Ge. In some cases, a Group III atom such as Ga and a Group V atom such as As serve as a donor or an acceptor inside a Group IV semiconductor such as Ge. Accordingly, when a semiconductor crystal layer is formed by epitaxial growth, it is necessary to avoid, as much as possible, mixing of an unintended impurity atom from a semiconductor crystal layer forming wafer or a sacrificial layer.

An object of the present invention is to inhibit mixing of an unintended impurity atom into a semiconductor crystal layer when a semiconductor crystal layer for transfer is formed by epitaxial growth.

### SUMMARY

To solve the above-mentioned problems, a first aspect of the present invention provides a semiconductor wafer comprising a sacrificial layer and a semiconductor crystal layer above a semiconductor crystal layer forming wafer, the semiconductor crystal layer forming wafer, the sacrificial layer and the semiconductor crystal layer being arranged in the order of the semiconductor crystal layer forming wafer, the sacrificial layer and the semiconductor crystal layer, wherein the semiconductor wafer comprises a diffusion inhibiting layer that inhibits diffusion of a first atom of one type selected from a plurality of types of atoms constituting the semiconductor crystal layer forming wafer or the sacrificial layer, at any cross-sectional position between (a) the interface of the semiconductor crystal layer forming wafer that faces the sacrificial layer and (b) a middle of the semiconductor crystal layer.

The semiconductor crystal layer forming wafer or the sacrificial layer may contain one or more types of Group V atoms, and in this case, the diffusion inhibiting layer may contain a Group V atom having a smaller atomic radius than one of the Group V atoms contained in the semiconductor crystal layer forming wafer or the sacrificial layer that occupies the largest percentage. Examples of the sacrificial layer include a Group III-V semiconductor layer, examples of the diffusion inhibiting layer include a Group III-V semiconductor layer, and examples of the semiconductor crystal layer include a Group IV semiconductor layer. More specifically, examples of the sacrificial layer include a layer that is made of AlₐGa_{b}In_{(1-a-b)As}_{c}P_{1-c} (0.9≦a≦1, 0≦b≦0.1, 0.9≦a+b≦1, 0<c≦1). More specifically, examples of the semiconductor crystal layer include a layer that is made of C_{d}SiₑGe_{f}Sn_{(1-d-e-f)} (0≦d<1, 0<e<1, 0<f≦1, 0<d+e+f≦1). In these cases, examples of the semiconductor crystal layer forming wafer include a wafer that is made of single-crystal GaAs or single-crystal Ge, examples of the sacrificial layer include a layer that is made of single-crystal AlAs, examples of the semiconductor crystal layer include a layer that is made of single-crystal Ge, examples of the diffusion inhibiting layer include a layer that is made of single-crystal InGaP and examples of the first atom include an Al, Ga or As atom.

When the diffusion inhibiting layer is positioned between the sacrificial layer and the semiconductor crystal layer, or within the semiconductor crystal layer, the semiconductor crystal layer forming wafer or the sacrificial layer may contain one or more atoms selected from a Ga atom and an As atom, and in this case, examples of the diffusion inhibiting layer include a Group III-V semiconductor crystal layer constituted with a Group III atom other than a Ga atom and a Group V atom other than an As atom. In this case, examples of the semiconductor crystal layer forming wafer include a wafer that is made of single-crystal GaAs or single-crystal Ge, examples of the sacrificial layer include a layer that is made of single-crystal AlAs, examples of the semiconductor crystal layer include a layer that is made of single-crystal Ge, examples of the diffusion inhibiting layer include a layer that is made of single-crystal InAlP and examples of the first atom include a Ga or As atom.

The half-value width of the diffraction spectrum of the (004) plane of the semiconductor crystal layer that is made of the single-crystal Ge is, for example, 40 arcsec or lower when measured using X-ray diffraction. The semiconductor crystal layer exhibits flatness of, for example, 2 nm or less when expressed in terms of the root mean square (RMS).

A second aspect of the present invention provides a method of producing a semiconductor wafer comprising: forming a sacrificial layer and a semiconductor crystal layer by epitaxial growth above a semiconductor crystal layer forming wafer in such a manner that the semiconductor crystal layer forming wafer, the sacrificial layer and the semiconductor crystal layer are arranged in the stated order; and after the formation of the sacrificial layer and before the formation of the semiconductor crystal layer, or during the formation of the semiconductor crystal layer, forming a diffusion inhibiting layer to inhibit diffusion of a first atom of one type selected from a plurality of types of atoms constituting the semiconductor crystal layer forming wafer or the sacrificial layer. Also, a third aspect of the present invention provides a method of producing a composite wafer using the semiconductor wafer produced by the above-described method, comprising: bonding the semiconductor wafer and a transfer target wafer in such a manner that a first surface of the semiconductor wafer faces a second surface of the transfer target wafer, the first surface being a surface of the semiconductor crystal layer or a surface of a layer formed above the semiconductor crystal layer, the first surface being designed to be brought into contact with the transfer target wafer or a layer formed on the transfer target wafer, the second surface being a surface of the transfer target wafer or a surface of the layer formed on the transfer target wafer, and the second surface being designed to be brought into contact with the first surface; and etching the sacrificial layer so that the transfer target wafer and the semiconductor wafer are separated from each other with the semiconductor crystal layer being left on the transfer target wafer.

The summary clause does not necessarily describe all necessary features of the embodiments of the present invention. The present invention may also be a sub-combination of the features described above.

### BRIEF DESCRIPTION OF THE DRAWINGS

FIG. 1 is a cross-sectional view illustrating a semiconductor wafer 100 relating to a first embodiment.

FIG. 2 is a cross-sectional view illustrating a modification of the semiconductor wafer 100.

FIG. 3 is a cross-sectional view illustrating a modification of the semiconductor wafer 100.

FIG. 4 is a cross-sectional view illustrating steps of a method of producing a composite wafer relating to a second embodiment in the performed order.

FIG. 5 is a cross-sectional view illustrating steps of a method of producing a composite wafer relating to a second embodiment in the performed order.

FIG. 6 is a cross-sectional view illustrating steps of a method of producing a composite wafer relating to a second embodiment in the performed order.

FIG. 7 is a cross-sectional view illustrating steps of a method of producing a composite wafer relating to a second embodiment in the performed order.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

### First Embodiment

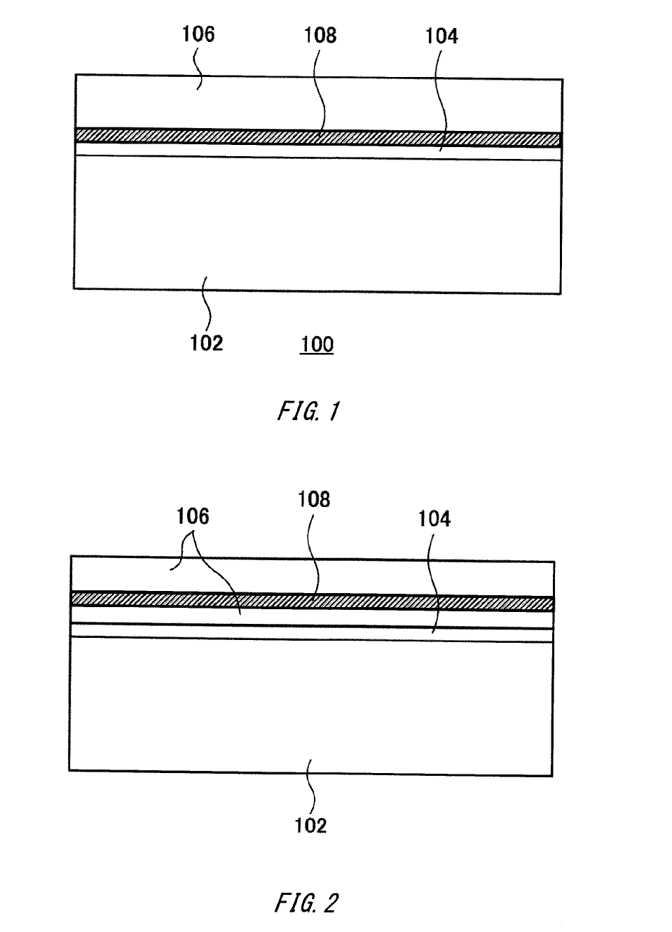

FIG. 1 is a cross-sectional view illustrating a semiconductor wafer 100 relating to a first embodiment. The semiconductor wafer 100 is a semiconductor wafer that can be used when a composite wafer having a semiconductor crystal layer is formed by epitaxial lift-off. The semiconductor wafer 100 includes a semiconductor crystal layer forming wafer 102, a sacrificial layer 104, a semiconductor crystal layer 106, and a diffusion inhibiting layer 108. The semiconductor crystal layer forming wafer 102, the sacrificial layer 104, the semiconductor crystal layer 106, and the diffusion inhibiting layer 108 are positioned in the order of the semiconductor crystal layer forming wafer 102, the sacrificial layer 104, the diffusion inhibiting layer 108, and the semiconductor crystal layer 106.

The semiconductor crystal layer forming wafer 102 is a wafer used to form a high-quality semiconductor crystal layer 106. A preferable material of the semiconductor crystal layer forming wafer 102 depends on the material of the semiconductor crystal layer 106, the method of forming the semiconductor crystal layer 106, and the like. Generally speaking, the semiconductor crystal layer forming wafer 102 is desirably made of a material that lattice-matches or pseudo-lattice-matches the semiconductor crystal layer 106 to be formed. For example, when a GaAs layer is formed by epitaxial growth as the semiconductor crystal layer 106, the semiconductor crystal layer forming wafer 102 is preferably a GaAs single-crystal wafer, and can be selected among InP, sapphire, Ge and SiC single-crystal wafers. When the semiconductor crystal layer forming wafer 102 is a GaAs single-crystal layer, the plane on which the semiconductor crystal layer 106 is formed is the (100) plane or (111) plane.

The sacrificial layer 104 is a layer that is used to separate the semiconductor crystal layer forming wafer 102 from the semiconductor crystal layer 106. Since the sacrificial layer 104 is removed by etching, the semiconductor crystal layer 106 is separated from the semiconductor crystal layer forming wafer 102. When the sacrificial layer 104 is etched, it is necessary to prevent at least a portion of the semiconductor crystal layer forming wafer 102 and the semiconductor crystal layer 106 from being etched away and to keep such a portion. Therefore, the etching rate of the sacrificial layer 104 needs to be higher than the etching rate of the semiconductor crystal layer forming wafer 102 and the semiconductor crystal layer 106, preferably several times or more. Examples of the sacrificial layer 104 include a Group III-V compound semiconductor layer. Specifically, examples of a material for the sacrificial layer 104 include AlₐGa_{b}In_{(1-a-b)}As_{c}P_{1-c} (0.9≦a≦1, 0≦b≦0.1, 0.9≦a+b≦1, 0<c≦1). When a GaAs single crystal wafer is selected as the semiconductor crystal layer forming wafer 102, and a GaAs layer is selected as the semiconductor crystal layer 106, the sacrificial layer 104 is preferably an AlAs layer. The sacrificial layer 104 may be selected among an InAlAs layer, an InGap layer, an InAlP layer, an InGaAlP layer, an AlSb layer, and an AlGaAs layer. As the thickness of the sacrificial layer 104 increases, the crystallinity of the semiconductor crystal layer 106 tends to degrade. Therefore, the sacrificial layer 104 is preferably as thin as possible as long as the sacrificial layer 104 can serve as a sacrificial layer. The thickness of the sacrificial layer 104 can be selected within the range of 0.1 nm to 10 μm.

The semiconductor crystal layer 106 is a transfer layer that is to be transferred onto a transfer target wafer (described later). The semiconductor crystal layer 106 is used as, for example, an active layer of a semiconductor device. The semiconductor crystal layer 106 can have high-quality crystallinity by being formed on the semiconductor crystal layer forming wafer 102 by epitaxial growth or the like. Furthermore, since the semiconductor crystal layer 106 is formed by being transferred onto the transfer target wafer, the semiconductor crystal layer 106 having high quality can be formed on any transfer target wafer without the need of considering whether the semiconductor crystal layer 106 lattice matches the transfer target wafer.

Examples of the semiconductor crystal layer 106 include a crystal layer made of a Group III-V compound semiconductor, a crystal layer made of a Group IV semiconductor, a crystal layer made of a Group II-VI compound semiconductor, or a laminate obtained by laminating a plurality of these crystal layers. Examples of the Group III-V compound semiconductor include AlᵤGaᵥIn₁₋ᵤ₋ᵥNₘPₙAs_{q}Sb_{1-m-n-q} (0≦u≦1, 0≦v≦1, 0≦m≦1, 0≦n≦1, 0≦q≦1), for example, GaAs, In_{y}Ga_{1-y}As (0<y<1), InP and GaSb. Examples of the Group IV semiconductor include C_{d}SiₑGe_{f}Sn_{(1-d-e-f)} (0≦d<1, 0≦e<1, 0<f≦1, 0<d+e+f≦1). Specifically, d=0 for example. That is, the examples include SiₑGe_{f}Sn_{(1-e-f)} (0≦e<1, 0<f≦1, 0<e+f≦1). More specifically, d=(1-e-f)=0 for example. That is, examples include GeₓSi₁₋ₓ (0<x≦1). Further specifically, x=1 for example. That is, the examples include Ge. Examples of the Group II-VI compound semiconductor include ZnO, ZnSe, ZnTe, CdS, CdSe and CdTe. When the Group IV semiconductor is GeₓSi₁₋ₓ (0<x<1), the Ge composition ratio x of GeₓSi₁₋ₓ is preferably 0.9 or higher. With the Ge composition ratio x that is 0.9 or higher, semiconductor characteristics similar to those of Ge can be obtained. By using the above-mentioned crystal layers or the laminate as the semiconductor crystal layer 106, the semiconductor crystal layer 106 can be used for an active layer of a high mobility field effect transistor, and particularly of a high mobility complementary field effect transistor.

The thickness of the semiconductor crystal layer 106 can be appropriately selected within the range of 0.1 nm to 500 μm. The thickness of the semiconductor crystal layer 106 is preferably no less than 0.1 nm and less than 1 μm. When the thickness of the semiconductor crystal layer 106 is less than 1 μm, the semiconductor crystal layer 106 can be used to form a composite wafer that is suitably used to produce a highly advanced transistor such as ultrathin-body MISFET.

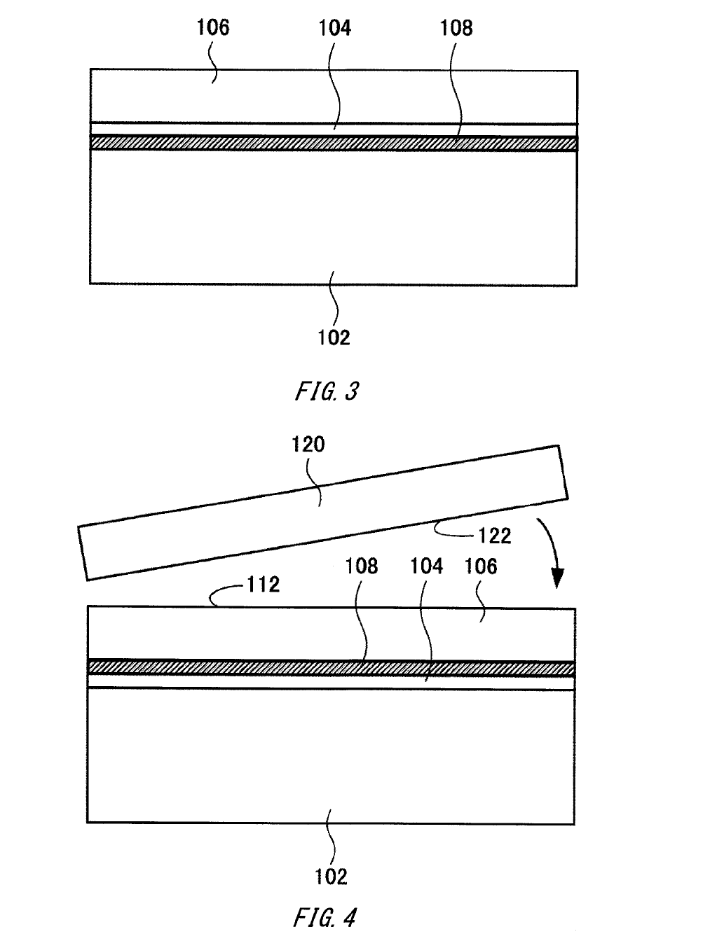

The diffusion inhibiting layer 108 inhibits diffusion of a first atom of one type selected from a plurality of types of atoms constituting the semiconductor crystal layer forming wafer 102 or the sacrificial layer 104. The diffusion inhibiting layer 108 can be formed at any cross-sectional position between (a) the interface of the semiconductor crystal layer forming wafer 102 that faces the sacrificial layer 104 (in the present example, the interface between the semiconductor crystal layer forming wafer 102 and the sacrificial layer 104) and (b) a middle of the semiconductor crystal layer 106. FIG. 1 illustrates the semiconductor wafer 100 in which the diffusion inhibiting layer 108 is positioned between the sacrificial layer 104 and the semiconductor crystal layer 106. Other than this, as illustrated in FIG. 2, the diffusion inhibiting layer 108 may be positioned within the semiconductor crystal layer 106, or as illustrated in FIG. 3, the diffusion inhibiting layer 108 may be positioned between the semiconductor crystal layer forming wafer 102 and the sacrificial layer 104.

When the diffusion inhibiting layer 108 is formed at any cross-sectional position between (a) the interface of the semiconductor crystal layer forming wafer 102 that faces the sacrificial layer 104 and (b) a middle of the semiconductor crystal layer 106, diffusion of the first atom from the semiconductor crystal layer forming wafer 102 can be inhibited. Because the first atom in many cases serves as a donor or an acceptor in the semiconductor crystal layer 106, it becomes a factor to lower the performance of the semiconductor crystal layer 106. However, by forming the diffusion inhibiting layer 108, entrance of the first atom into the semiconductor crystal layer 106 can be inhibited, and a high quality semiconductor crystal layer 106 can be provided. When the diffusion inhibiting layer 108 is formed between the sacrificial layer 104 and the semiconductor crystal layer 106 as illustrated in FIG. 1 or 2, diffusion of the first atom from the sacrificial layer 104 can be inhibited, and the quality of the semiconductor crystal layer 106 can be further enhanced. Examples of the diffusion inhibiting layer 108 include a Group III-V semiconductor. More specific examples of the material for the diffusion inhibiting layer 108 include InGaP and InAlP.

When the diffusion inhibiting layer 108 is InGaP, its thickness may be within the range of 5 nm to 1000 nm, preferably within the range of 10 nm to 500 nm, and further preferably within the range of 50 nm to 100 nm. When the diffusion inhibiting layer 108 is InAlP, its thickness may be within the range of 5 nm to 1000 nm, preferably within the range of 10 nm to 500 nm, and further preferably in the range of 50 nm to 100 nm. The preferred range of the thickness of the diffusion inhibiting layer 108 varies depending on the temperature at which the semiconductor crystal layer 106 is formed thereon, and the duration during which the semiconductor crystal layer 106 is formed (thickness). For example, when the semiconductor crystal layer 106 is formed at 600° C. to 650° C. over 1 to 10 minutes, the thickness is preferably 50 nm to 100 nm if the diffusion inhibiting layer 108 is InGaP, and preferably 50 nm to 100 nm if the diffusion inhibiting layer 108 is InAlP.

When the semiconductor crystal layer forming wafer 102 or the sacrificial layer 104 contains one or more types of Group V atoms, the diffusion inhibiting layer 108 contains a Group V atom having a smaller atomic radius than one of the Group V atoms contained in the semiconductor crystal layer forming wafer 102 or the sacrificial layer 104 that occupies the largest percentage. For example, when the Group V atom contained in the semiconductor crystal layer forming wafer 102 or the sacrificial layer 104 is an As atom, the diffusion inhibiting layer 108 preferably consists of a Group III-V semiconductor containing P that is a Group V atom having an atomic radius smaller than that of an As atom, for example InGaP. When the Group V atoms contained in the semiconductor crystal layer forming wafer 102 or the sacrificial layer 104 are an As atom and a P atom, and the As atom is the atom, among the Group V atoms contained in the semiconductor crystal layer forming wafer 102 or the sacrificial layer 104, that occupies the largest percentage, the diffusion inhibiting layer 108 is preferably a Group III-V semiconductor crystal layer containing a P atom or a N atom having an atomic radius smaller than that of the As atom. Examples of the Group III-V semiconductor containing a P atom or a N atom include InGaP, InAlP, InGaN and AlGaN. Because the diffusion inhibiting layer 108 is a Group III-V semiconductor crystal layer containing a Group V atom having an atomic radius smaller than that of the Group V atom contained in the semiconductor crystal layer forming wafer 102 or the sacrificial layer 104 that occupies the largest percentage, the binding energy among the Group III-V atoms in the diffusion inhibiting layer 108 is high, and the ability to inhibit diffusion of the first atom can be enhanced.

Examples of the sacrificial layer 104 include a Group III-V semiconductor layer, examples of the diffusion inhibiting layer 108 include a Group III-V semiconductor layer, and examples of the semiconductor crystal layer 106 include a Group IV semiconductor layer. For example, when the semiconductor crystal layer forming wafer 102 is made of single crystal GaAs or single crystal Ge, the sacrificial layer 104 is made of single crystal AlAs, the semiconductor crystal layer 106 is made of single crystal Ge, and the diffusion inhibiting layer 108 is made of single crystal InGaP, examples of the first atom include an Al atom, a Ga atom and an As atom.

When the diffusion inhibiting layer 108 is positioned between the sacrificial layer 104 and the semiconductor crystal layer 106 or positioned within the semiconductor crystal layer 106, the semiconductor crystal layer forming wafer 102 or the sacrificial layer 104 may contain one or more atoms that are selected from a Ga atom and an As atom. In this case, the diffusion inhibiting layer 108 is preferably a Group III-V semiconductor crystal layer constituted with a Group III atom other than a Ga atom and a Group V atom other than an As atom. Because the diffusion inhibiting layer 108 does not contain a Ga atom and an As atom, a Ga atom and an As atom are never supplied from the diffusion inhibiting layer 108, and the purity of the semiconductor crystal layer 106 can be enhanced further. In this case, examples of the semiconductor crystal layer forming wafer 102 include a single crystal GaAs wafer and a single crystal Ge wafer, examples of the sacrificial layer 104 include a single crystal AlAs layer, examples of the semiconductor crystal layer 106 include a single crystal Ge layer, examples of the diffusion inhibiting layer 108 include a single crystal InAlP layer, and examples of the first atom include a Ga atom and an As atom.

When the semiconductor crystal layer 106 is made of single crystal Ge, the half-value width of the diffraction spectrum of the (004) plane may be 40 arcsec or lower when measured using X-ray diffraction. Also, the semiconductor crystal layer 106 exhibits flatness of 2 nm or less when expressed in terms of the root mean square (RMS). When required, a surface of the semiconductor crystal layer 106 may be polished to be flat. Note that a buffer layer may be formed between the semiconductor crystal layer forming wafer 102 and the sacrificial layer 104. When the semiconductor crystal layer forming wafer 102 is a GaAs wafer, examples of the buffer layer include a GaAs layer.

The semiconductor wafer 100 relating to the first embodiment may be produced by sequentially forming the sacrificial layer 104, the diffusion inhibiting layer 108 and the semiconductor crystal layer 106 on the semiconductor crystal layer forming wafer 102.

The sacrificial layer 104 can be formed by epitaxial growth, chemical vapor deposition (CVD), sputtering or atomic layer deposition (ALD), etc. The epitaxial growth can include metal organic chemical vapor deposition (MOCVD) or molecular beam epitaxy (MBE). When the sacrificial layer 104 is formed by MOCVD, the source gas can be trimethylgallium (TMGa), trimethylaluminum (TMA), trimethylindium (TMIn), arsine (AsH₃), phosphine (PH₃) or the like. The carrier gas can be hydrogen. Alternatively, a compound that is obtained by replacing some of the hydrogen atom groups of the above-described source gas with a chlorine atom or a hydrocarbon group can be used. The growth temperature (which is also referred to as the reaction temperature) can be selected appropriately within the range of 300° C. to 900° C., preferably within the range of 400° C. to 800° C. The thickness of the sacrificial layer 104 can be controlled by appropriately determining the amount of the source gas to be supplied and the duration of the reaction.

The diffusion inhibiting layer 108 can be formed by epitaxial growth or ALD. The epitaxial growth can include MOCVD and MBE. When the diffusion inhibiting layer 108 is made of a Group III-V compound semiconductor and formed by MOCVD, the source gas can be trimethylgallium (TMGa), trimethylaluminum (TMA), trimethylindium (TMIn), arsine (AsH₃), phosphine (PH₃) or the like. The carrier gas can be hydrogen. Alternatively, a compound that is obtained by replacing some of the hydrogen atom groups of the above-described source gas with a chlorine atom or a hydrocarbon group can be used. The growth temperature can be selected appropriately within the range of 300° C. to 900° C., preferably within the range of 400° C. to 800° C. The thickness of the diffusion inhibiting layer 108 can be controlled by appropriately determining the amount of the source gas to be supplied and the duration of the reaction.

The semiconductor crystal layer 106 can be formed by epitaxial growth or ALD. The epitaxial growth can include MOCVD and MBE. When the semiconductor crystal layer 106 is made of a Group III-V compound semiconductor and formed by MOCVD, the source gas can be trimethylgallium (TMGa), trimethylaluminum (TMA), trimethylindium (TMIn), arsine (AsH₃), PH₃ (phosphine) or the like. When the semiconductor crystal layer 106 is made of a Group IV compound semiconductor and formed by CVD, the source gas can be germane (GeH₄), silane (SiH₄), disilane (Si₂H₆) or the like. The carrier gas can be hydrogen. Alternatively, a compound that is obtained by replacing some of the hydrogen atom groups of the above-described source gas with a chlorine atom or a hydrocarbon group can be used. The growth temperature can be selected appropriately within the range of 300° C. to 900° C., preferably within the range of 400° C. to 800° C. The thickness of the semiconductor crystal layer 106 can be controlled by appropriately determining the amount of the source gas to be supplied and the duration of the reaction.

### Second Embodiment

FIGS. 4 to 7 are cross-sectional views illustrating steps of a method of producing a composite wafer relating to the second embodiment in the performed order. The production method relating to the second embodiment uses the semiconductor wafer 100 described in the first embodiment. The semiconductor wafer 100 is prepared as described in the first embodiment.

Next, as illustrated in FIG. 4, a surface of the transfer target wafer 120 and a surface of the semiconductor crystal layer 106 of the semiconductor crystal layer forming wafer 102 are caused to face each other. Here, the surface of the semiconductor crystal layer 106 is a surface of a layer formed on the semiconductor crystal layer forming wafer 102, and is an example of a “first surface 112” which is to be brought into contact with the transfer target wafer 120 or a layer formed on the transfer target wafer 120. Also, the surface of the transfer target wafer 120 is a surface of the transfer target wafer 120 or a layer formed on the transfer target wafer 120, and is an example of a “second surface 122” which is to be brought into contact with the first surface 112.

The transfer target wafer 120 is a wafer to which the semiconductor crystal layer 106 is to be transferred. The transfer target wafer 120 can be a target wafer on which an electronic device that uses the semiconductor crystal layer 106 as an active layer is eventually formed, or a provisional wafer on which the semiconductor crystal layer 106 is temporarily placed until the semiconductor crystal layer 106 is transferred onto the target wafer. That is, the semiconductor crystal layer 106 may be transferred from the transfer target wafer 120 further to another wafer. The transfer target wafer 120 may be made of any of organic materials or inorganic materials. Examples of the transfer target wafer 120 include a silicon wafer, a silicon-on-insulator (SOI) wafer, a glass wafer, a sapphire wafer, a SiC wafer, and an AN wafer. Alternatively, the transfer target wafer 120 may be an insulative wafer such as a ceramics wafer or a plastic wafer, or an electrically-conductive wafer made of a metal, for example. When the transfer target wafer 120 is a silicon wafer or SOI wafer, a production apparatus that is used for existing silicon processes can be used. The research, development and production can be conducted more efficiently utilizing the common knowledge known in the field of silicon processes.

When the transfer target wafer 120 is a hard wafer that does not easily bend, such as a silicon wafer, the semiconductor crystal layer 106 to be transferred is protected against mechanical vibration and the like and the high crystallinity of the semiconductor crystal layer 106 can be maintained. When the transfer target wafer 120 is a flexible wafer such as a plastic wafer, the transfer target wafer 120 and the semiconductor crystal layer forming wafer 102 can be quickly separated by bending the flexible wafer in the direction of separating from the semiconductor crystal layer forming wafer 102, and supplying an etching solution promptly, at a step of etching the sacrificial layer 104 described later.

As illustrated in FIG. 5, the transfer target wafer 120 is bonded to the semiconductor crystal layer forming wafer 102 in such a manner that the surface of the semiconductor crystal layer 106, which is the first surface 112, is bonded to the surface of the transfer target wafer 120, which is the second surface 122.

At the time of bonding, adhesiveness enhancement treatment to enhance the adhesiveness between the transfer target wafer 120 and the semiconductor crystal layer 106 may be performed on the surface of the transfer target wafer 120 (the second surface 122) and the surface of the semiconductor crystal layer 106 (the first surface 112). The adhesiveness enhancement treatment may be performed only on one of the surface of the transfer target wafer 120 (the second surface 122) and the surface of the semiconductor crystal layer 106 (the first surface 112). The adhesiveness enhancement treatment can be, for example, ion beam activation performed by an ion beam generator. The applied ions are, for example, argon ions. The adhesiveness enhancement treatment may be plasma activation. The plasma activation can be, for example, an oxygen plasma treatment. The adhesiveness enhancement treatment can contribute to the enhancement of the adhesiveness between the transfer target wafer 120 and the semiconductor crystal layer 106. The adhesiveness enhancement treatment may be replaced with a step of forming in advance an adhesive layer on the transfer target wafer 120. When the adhesiveness enhancement treatment is performed, the bonding step can be performed at room temperature.

Also, following the bonding, the transfer target wafer 120 may be attached onto the semiconductor crystal layer forming wafer 102 under pressure by applying a load to the transfer target wafer 120 and the semiconductor crystal layer forming wafer 102. The step of attaching under pressure can contribute to the improvement of the adhesiveness strength. During or after the step of attaching under pressure, a thermal treatment may be performed. The temperature at which the thermal treatment takes place is preferably within the range of 50° C. to 600° C., further preferably within the range of 100° C. to 400° C. The load can be selected as appropriate within the range of 1 MPa to 1 GPa. Note that, when the transfer target wafer 120 is attached onto the semiconductor crystal layer forming wafer 102 using an adhesive layer, the attaching step under pressure is not necessary.

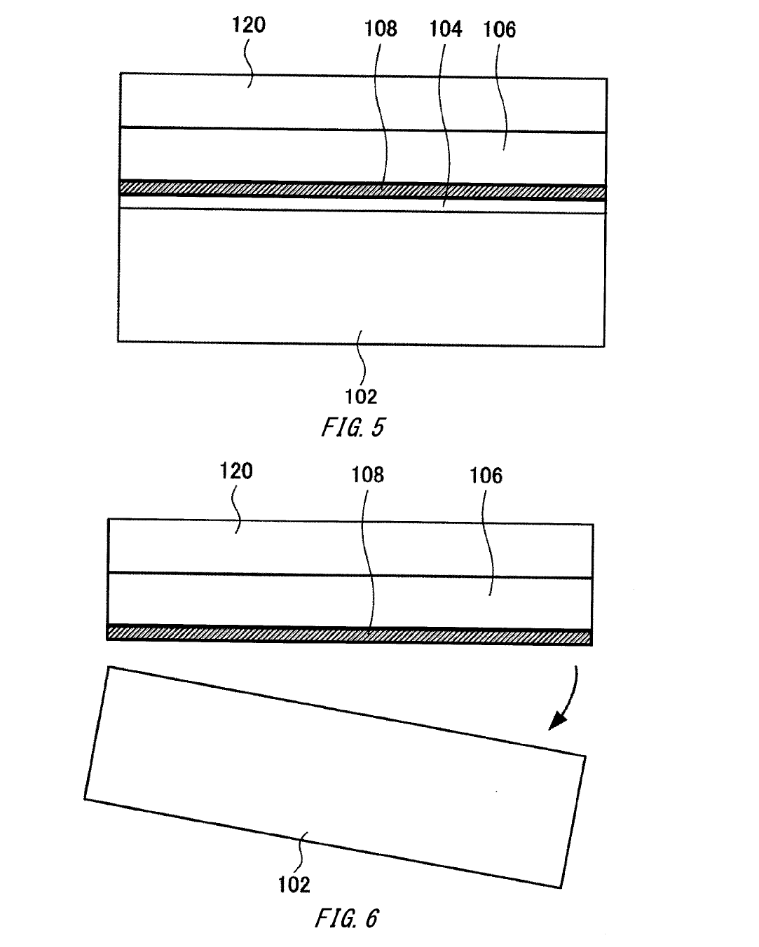

Subsequently, as shown in FIG. 6, the semiconductor crystal layer forming wafer 102 and the transfer target wafer 120 are entirely or partially (preferably, entirely) immersed into an etching solution to etch the sacrificial layer 104. If the sacrificial layer 104 is etched away, the transfer target wafer 120 can be separated from the semiconductor crystal layer forming wafer 102 with the semiconductor crystal layer 106 is left on the transfer target wafer 120.

The sacrificial layer 104 can be selectively etched away. Here, the expression “to selectively etch away” means that the sacrificial layer 104 is “selectively” etched away substantially alone by selecting the etching solution and other conditions in such a manner that the sacrificial layer 104 and other constituents, for example, the semiconductor crystal layer 106, are similarly exposed to the etching solution and etched away but the etching rate of the sacrificial layer 104 is controlled to be higher than the etching rate of the other constituents. When the sacrificial layer 104 is an AlAs layer, the etching solution can be, for example, HCl, HF, phosphoric acid, citric acid, hydrogen peroxide solution, ammonia, an aqueous solution of sodium hydroxide or water. During the etching, the temperature is preferably controlled to fall within the range of 10° C. to 90° C. The duration of the etching can be controlled as appropriate to fall within the range of 1 minute to 200 hours.

The sacrificial layer 104 can also be etched away with an ultrasonic wave being applied to the etching solution. The application of an ultrasonic wave can increase the etching rate. Furthermore, while the etching is being performed, a ultraviolet ray may be applied or the etching solution may be stirred. Here, the above describes an exemplary case where the sacrificial layer 104 is etched using the etching solution. However, the sacrificial layer 104 can be etched away using dry etching.

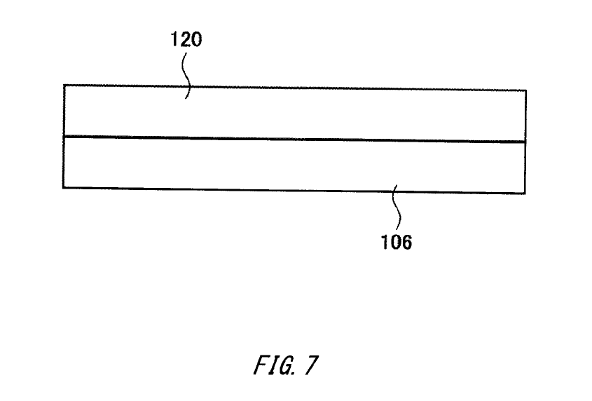

If the sacrificial layer 104 is removed by the etching in the above-described manner, the transfer target wafer 120 is separated from the semiconductor crystal layer forming wafer 102 with the semiconductor crystal layer 106 being left on the transfer target wafer 120. Thus, the semiconductor crystal layer 106 is transferred onto the transfer target wafer 120. Furthermore, when the diffusion inhibiting layer 108 is removed, a composite wafer having the semiconductor crystal layer 106 is produced on the transfer target wafer 120 as illustrated in FIG. 7.

In the above-mentioned method of producing the composite wafer relating to the first embodiment, the semiconductor crystal layer 106 in which diffusion of an impurity atom is inhibited by the diffusion inhibiting layer 108 and whose purity is kept high can be formed on the transfer target wafer 120.

Note that although in the above-mentioned second embodiment, the semiconductor crystal layer 106 is transferred from the semiconductor crystal layer forming wafer 102 to the transfer target wafer 120, it may be transferred further to another transfer target wafer. Also, an adhesive layer may be formed between the semiconductor crystal layer 106 and the transfer target wafer 120 as appropriate. The adhesive layer may be made of any of organic materials or inorganic materials. Examples of the organic material adhesive layer include a polyimide film or a resist film. In this case, the adhesive layer can be formed by coating such as spin coating. When made of an inorganic material, the adhesive layer can be, for example, a layer made of at least one of Al₂O₃, AN, Ta₂O₅, ZrO₂, HfO₂, SiO, (for example, SiO₂), SiNₓ (for example, Si₃N₄), and SiOₓN_{y}, or a laminate obtained by stacking at least two layers respectively made of the above-listed materials. In this case, the adhesive layer can be formed by ALD, thermal oxidation, evaporation, CVD or sputtering. The thickness of the adhesive layer can be within the range of 0.1 nm to 100 μm.

Also, after the sacrificial layer 104, the diffusion inhibiting layer 108, and the semiconductor crystal layer 106 are formed on the semiconductor crystal layer forming wafer 102 and before the semiconductor crystal layer forming wafer 102 and the transfer target wafer 120 are bonded to each other, an electronic device whose active region is constituted by a portion of the semiconductor crystal layer 106 may be formed on the semiconductor crystal layer 106. In this case, the semiconductor crystal layer 106 is transferred with the electronic device being formed thereon. Since the semiconductor crystal layer 106 is flipped each time it is transferred, this method enables electronic devices to be formed on both of the front and back planes of the semiconductor crystal layer 106.

In the above description of the embodiments, the final wafer to which the semiconductor crystal layer 106 is eventually transferred is not specifically mentioned. The final wafer may be a semiconductor wafer such as a silicon wafer, an SOI wafer or a wafer in which a semiconductor layer is formed on an insulative wafer. On the semiconductor wafer, the SOI layer or the semiconductor layer, an electronic device such as a transistor may be formed in advance. In other words, the semiconductor crystal layer 106 can be formed by the transfer technique using the above-described methods on the wafer on which the electronic device has already been formed. Using this technique, semiconductor devices that are significantly different in composition, material or the like can be monolithically formed. In particular, if an electronic device is formed in advance on the semiconductor crystal layer 106, and the semiconductor crystal layer 106 is subsequently formed by the transfer technique on the above-described wafer on which an electronic device has already been formed, the electronic devices that are made of heterogeneous materials and produced using significantly different production processes can be easily monolithically formed.

The above-mentioned embodiments may be changed as described below. That is, a GaAs wafer may be used as the semiconductor crystal layer forming wafer 102, and for example an AlAs layer may be formed as the sacrificial layer 104 on the semiconductor crystal layer forming wafer 102. The AlAs layer may be formed by crystal growth using epitaxial growth by low-pressure MOCVD, for example with trimethylaluminum (TMAl) and arsine (AsH₃) as its raw materials at the growth temperature of 600° C. The semiconductor crystal layer 106 is formed on the sacrificial layer 104. The semiconductor crystal layer 106 in the present example has a first Ge layer, a second Ge layer and a third Ge layer. The first Ge layer is formed on the sacrificial layer 104. The first Ge layer may be formed by crystal growth using epitaxial growth by low pressure CVD, for example with monogermane (GeH₄) as its raw material at the growth temperature of 550° C., and the reaction temperature of 40 Torr. The thickness of the AlAs layer and the first Ge layer may be 150 nm and 100 nm, respectively.

The semiconductor crystal layer forming wafer 102 is taken out of a reaction chamber and placed in a spare room, the reaction chamber is cleaned for example by etching using hydrogen chloride gas, and thereafter the semiconductor crystal layer forming wafer 102 having been placed in the spare room is returned to the reaction chamber. Then, the second Ge layer is further formed on the first Ge layer. The second Ge layer may be formed to the thickness of 100 nm, for example. The second Ge layer may be formed by crystal growth using epitaxial growth by low pressure CVD, with monogermane (GeH₄) as its raw material at the growth temperature of 650° C., and the reaction pressure of 6 Torr. As the diffusion inhibiting layer 108, an InGap layer or an InAlP layer can be further formed on the second Ge layer by using epitaxial growth by low-pressure MOCVD. The third Ge crystal layer similar to the second Ge layer can be formed on the InGap layer or the InAlP layer which is the diffusion inhibiting layer 108. Tue thickness of the third Ge layer may be 1.0 μm, for example. In this manner, a semiconductor wafer having the diffusion inhibiting layer 108 (an InGap layer or an InAlP layer) within the semiconductor crystal layer 106 can be produced.

### EXAMPLE

As the semiconductor crystal layer forming wafer 102, a GaAs wafer having a 2° inclination from the (100) plane to the (110) plane and a 150 mm diameter was used. As the diffusion inhibiting layer 108m an InGap layer was formed on the GaAs wafer by crystal growth using epitaxial growth by low-pressure MOCVD. As the sacrificial layer 104, an AlAs layer was formed by crystal growth on the InGap layer by using epitaxial growth by low-pressure MOCVD. Trimethylaluminum (TMAl) and arsine (AsH₃) were used as the raw materials for epitaxial growth of the AlAs layer, and the growth temperature was 600° C. As the semiconductor crystal layer 106, a Ge layer was formed by crystal growth on the AlAs layer by using epitaxial growth by low pressure CVD. Monogermane (GeH₄) was used as the raw material for epitaxial growth of the Ge layer, the growth temperature was 650° C., and the reaction pressure was 6 Torr. In this manner, a semiconductor wafer having, sequentially, the InGap layer, the AlAs layer and the Ge layer on the GaAs wafer was produced. The thickness of the InGap layer, the AlAs layer and the Ge layer was 100 nm, 150 nm and 1.4 μm, respectively.

### Comparative Example

A semiconductor wafer not having a diffusion inhibiting layer was produced as a comparative example. That is, by using a GaAs wafer similar to the example, but without forming a diffusion inhibiting layer, an AlAs layer similar to the example was produced as the sacrificial layer 104, and a Ge layer similar to the example was formed as the semiconductor crystal layer 106. However, between the AlAs layer and the Ge layer, a Ge layer was formed to have a thickness of 100 nm at the growth temperature of 550° C. and the reaction pressure of 40 Torr.

The Ge layers having a thickness of 1.4 μm of the semiconductor wafer of the example and the semiconductor wafer of the comparative example 1 were analyzed by secondary ion mass spectrum (SIMS). The average value of Ga concentration between the positions at the depth of 0.1 μm and 0.2 μm from the surface of the Ge layer of the example was 1.3×10¹⁶ cm⁻³. On the contrary, in SIMS analysis of the comparative example performed under similar conditions showed the average value of Ga concentration of 1.9×10¹⁷ cm⁻³. The semiconductor wafer of the example showed an effect of inhibiting a Ga atom by one digit or more as compared with the comparative example.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor wafer comprising a sacrificial layer and a semiconductor crystal layer above a semiconductor crystal layer forming wafer, the semiconductor crystal layer forming wafer, the sacrificial layer and the semiconductor crystal layer being arranged in the order of the semiconductor crystal layer forming wafer, the sacrificial layer and the semiconductor crystal layer, wherein
the semiconductor wafer comprises a diffusion inhibiting layer that inhibits diffusion of a first atom of one type selected from a plurality of types of atoms constituting the semiconductor crystal layer forming wafer or the sacrificial layer, at any cross-sectional position between (a) the interface of the semiconductor crystal layer forming wafer that faces the sacrificial layer and (b) a middle of the semiconductor crystal layer.

2. The semiconductor wafer as set forth in claim 1, wherein
the semiconductor crystal layer forming wafer or the sacrificial layer contains one or more types of Group V atoms, and
the diffusion inhibiting layer contains a Group V atom having a smaller atomic radius than one of the Group V atoms contained in the semiconductor crystal layer forming wafer or the sacrificial layer that occupies the largest percentage.

3. The semiconductor wafer as set forth in claim 1, wherein
the sacrificial layer is made of a Group III-V semiconductor,
the diffusion inhibiting layer is made of a Group III-V semiconductor, and
the semiconductor crystal layer is made of a Group IV semiconductor.

4. The semiconductor wafer as set forth in claim 3, wherein
the sacrificial layer is made of AlₐGa_{b}In_{(1-a-b)}As_{c}P_{1-c} (0.9≦a≦1, 0≦b≦0.1, 0.9≦a+b≦1, 0<c≦1).

5. The semiconductor wafer as set forth in claim 3, wherein
the semiconductor crystal layer is made of C_{d}SiₑGe_{f}Sn_{(1-d-e-f)} (0≦d<1, 0≦e<1, 0<f≦1, 0<d+e+f≦1).

6. The semiconductor wafer as set forth in claim 3, wherein
the semiconductor crystal layer forming wafer is made of single-crystal GaAs or single-crystal Ge,
the sacrificial layer is made of single-crystal AlAs,
the semiconductor crystal layer is made of single-crystal Ge,
the diffusion inhibiting layer is made of single-crystal InGaP and
the first atom is an Al, Ga or As atom.

7. The semiconductor wafer as set forth in claim 3, wherein
the diffusion inhibiting layer is positioned between the sacrificial layer and the semiconductor crystal layer, or within the semiconductor crystal layer,
the semiconductor crystal layer forming wafer or the sacrificial layer contains one or more atoms selected from a Ga atom and an As atom, and
the diffusion inhibiting layer is a Group III-V semiconductor crystal layer constituted with a Group III atom other than a Ga atom and a Group V atom other than an As atom.

8. The semiconductor wafer as set forth in claim 7, wherein
the semiconductor crystal layer forming wafer is made of single-crystal GaAs or single-crystal Ge,
the sacrificial layer is made of single-crystal AlAs,
the semiconductor crystal layer is made of single-crystal Ge,
the diffusion inhibiting layer is made of single-crystal InAlP and
the first atom is a Ga or As atom.

9. The semiconductor wafer as set forth in claim 6, wherein
the half-value width of the diffraction spectrum of the (004) plane of the semiconductor crystal layer that is made of the single-crystal Ge is 40 arcsec or lower when measured using X-ray diffraction.

10. The semiconductor wafer as set forth in claim 9, wherein
the semiconductor crystal layer exhibits flatness of 2 nm or less when expressed in terms of the root mean square (RMS).

11. A method of producing a semiconductor wafer comprising:
forming a sacrificial layer and a semiconductor crystal layer by epitaxial growth above a semiconductor crystal layer forming wafer in such a manner that the semiconductor crystal layer forming wafer, the sacrificial layer and the semiconductor crystal layer are arranged in the stated order; and
after the formation of the sacrificial layer and before the formation of the semiconductor crystal layer, or during the formation of the semiconductor crystal layer, forming a diffusion inhibiting layer to inhibit diffusion of a first atom of one type selected from a plurality of types of atoms constituting the semiconductor crystal layer forming wafer or the sacrificial layer.

12. A method of producing a composite wafer using the semiconductor wafer produced by the method as set forth in claim 11, comprising:
bonding the semiconductor wafer and a transfer target wafer in such a manner that a first surface of the semiconductor wafer faces a second surface of the transfer target wafer, the first surface being a surface of the semiconductor crystal layer or a surface of a layer formed above the semiconductor crystal layer, the first surface being designed to be brought into contact with the transfer target wafer or a layer formed on the transfer target wafer, the second surface being a surface of the transfer target wafer or a surface of the layer formed on the transfer target wafer, and the second surface being designed to be brought into contact with the first surface; and
etching the sacrificial layer so that the transfer target wafer and the semiconductor wafer are separated from each other with the semiconductor crystal layer being left on the transfer target wafer.
